(19) United States
(12) Patent Application Publication
(10) Pub. No.: US 2018/0102308 A1
(43) Pub. Date: Apr. 12, 2018

(54) SEMICONDUCTOR DEVICE AND SEMICONDUCTOR MODULE

(71) Applicant: KABUSHIKI KAISHA TOSHIBA, Tokyo (JP)

(72) Inventors: Tatsuya NISHIWAKI, Nonoichi (JP); Shunsuke KATOH, Komatsu (JP); Masatoshi ARAI, Hakusan (JP); Chikako YOSHIOKA, Kanazawa (JP); Bungo TANAKA, Nonoichi (JP); Shinya OZAWA, Kanazawa (JP); Takahiro KAWANO, Nonoichi (JP)

(73) Assignee: KABUSHIKI KAISHA TOSHIBA, Tokyo (JP)

(21) Appl. No.: 15/446,589

(22) Filed: Mar. 1, 2017

(30) Foreign Application Priority Data
Oct. 11, 2016 (JP) 2016-200199

(51) Int. Cl. H01L 23/495

(52) U.S. Cl. CPC H01L 23/49562; H01L 23/4952

(57) ABSTRACT

In some embodiments, a semiconductor device includes a semiconductor chip including a first terminal, a second terminal and a third terminal, a frame electrically coupled to the second terminal, the frame mounting the semiconductor chip, a first conductor including a chip connection electrically coupled to the first terminal, a first connection connecting to the chip connection and protruding from the chip connection, and a second connection connecting to the chip connection, protruding from the chip connection, and being provided physically spaced from the first connection. The semiconductor device further includes a second conductor electrically coupled to the third terminal.

### CROSS-REFERENCE TO RELATED APPLICATIONS

This application claims the benefit of and priority to Japanese Patent Application No. 2016-200199, filed on Oct. 11, 2016; the entire contents of which are incorporated herein by reference.

### FIELD

Embodiments described herein relate generally to a semiconductor device and a semiconductor module.

### BACKGROUND

A MOSFET (Metal Oxide Semiconductor Field Effect Transistor) can be used in some power switching devices.

In some cases, a parasitic inductor may be formed on a source connector and a mounting board of a MOSFET including three terminals: a gate electrode, a source electrode, and a drain electrode. A problem may arise in that noise caused by the parasitic inductor may be added to a drain current.

### SUMMARY

In some embodiments, according to an aspect, a semiconductor device includes a semiconductor chip including a first terminal, a second terminal and a third terminal, a frame electrically coupled to the second terminal, the frame mounting the semiconductor chip, a first conductor including a chip connection electrically coupled to the first terminal, a first connection connecting to the chip connection and protruding from the chip connection, and a second connection connecting to the chip connection, protruding from the chip connection, and being provided physically spaced from the first connection. The semiconductor device further includes a second conductor electrically coupled to the third terminal.

In some embodiments, according to another aspect, a semiconductor module includes a semiconductor chip including a first terminal, a second terminal and a third terminal, a frame electrically coupled to the second terminal, the frame mounting the semiconductor chip, a first conductor comprising, a chip connection electrically coupled to the first terminal, a first connection connecting to the chip connection and protruding from the chip connection, a second connection connecting to the chip connection, protruding from the chip connection, and being provided physically spaced from the first connection, a second conductor electrically coupled to the third terminal, and a gate driver connected to the second connection and the second conductor.

### BRIEF DESCRIPTION OF THE DRAWINGS

FIG. 1 is a top view showing some embodiments of a semiconductor device according to some embodiments of a first aspect.

FIG. 2 is an A-A′ cross-sectional view of the embodiments shown in FIG. 1.

FIG. 3 is a circuit diagram showing some embodiments of a semiconductor device according to the first aspect connected to a boost chopper.

FIG. 4 is a top view showing some embodiments of a semiconductor device according a first comparative example.

FIG. 5 is a circuit diagram showing some embodiments of the semiconductor device according to the first comparative example connected to a boost chopper.

FIG. 6 is a top view showing some embodiments of a semiconductor device according to a second comparative example.

FIG. 7 is a top view showing some embodiments of a semiconductor device according to a first modification of the first aspect.

FIG. 8 is a top view showing some embodiments of a semiconductor device according to a second modification of the first aspect.

### DETAILED DESCRIPTION

Embodiments of the disclosure will now be described with reference to the drawings. In the drawings and the specification of the application, similar components may be marked or referred to by same reference numerals and/or letters, and a detailed description thereof may be omitted, as appropriate.

### (First Aspect)

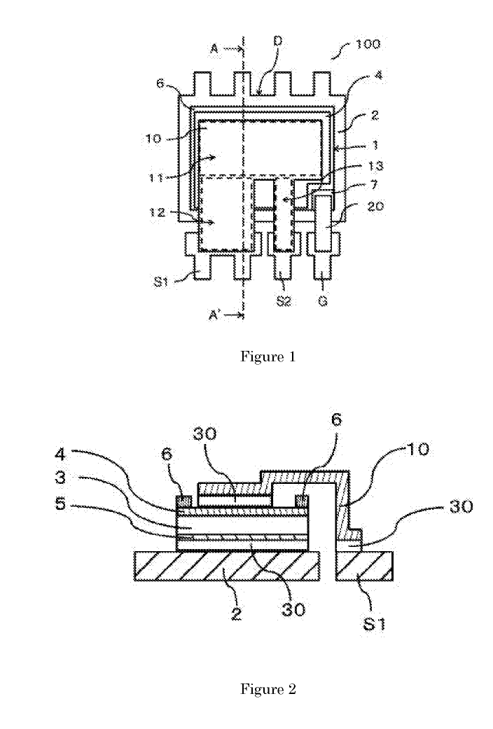

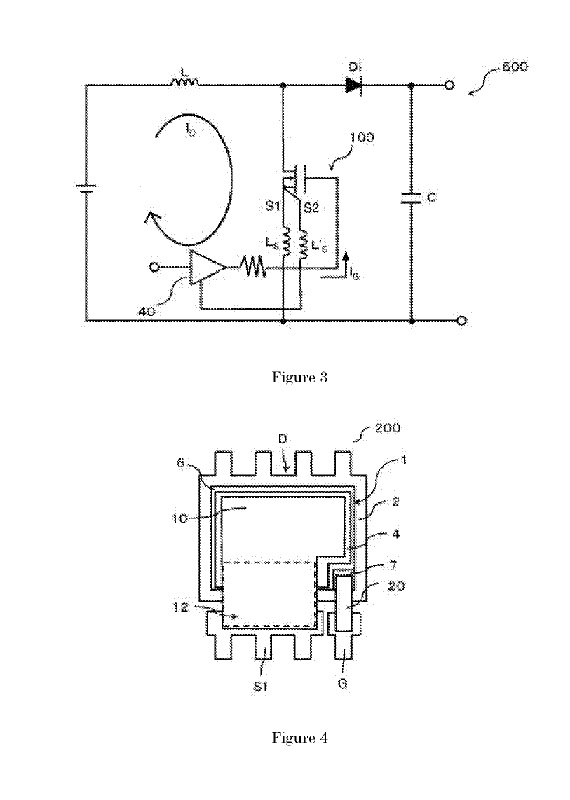

Some embodiments of a semiconductor device according to a first aspect will now be described with reference to FIG. 1, FIG. 2 and FIG. 3.

FIG. 1 is a top view showing some embodiments of a semiconductor device 100 according to the first aspect. FIG. 2 is an A-A′ cross-sectional view of the embodiments shown in FIG. 1.

The semiconductor device 100 according to the first aspect includes a small outline package (SOP). The SOP includes a structure in which terminals protrude from two opposing surfaces of the SOP. The SOP described herein includes eight terminals; however, the SOP may include a different number of terminals (e.g. less than eight terminals or more than eight terminals).

As shown in FIG. 1, the semiconductor device 100 includes a semiconductor chip 1, a frame 2 (drain connector), a passivation layer 6, a source connector 10 (a first conductor), a gate connector (a second conductor), a solder 30, a source terminal S1, a kelvin-source terminal S2, and a gate connector G.

The semiconductor chip 1 is, for example, a MOSFET. The semiconductor chip 1 includes a semiconductor layer 3, a source electrode 4 (a first electrode), a drain electrode 5 (a second electrode), and a gate electrode 7 (a third electrode). The semiconductor layer 3 has a first side (front side in the FIG. 1) and a second side (underside in FIG. 1) opposed to each other. The source electrode 4 and the gate electrode 7 are provided on the first side. The drain electrode 7 is provided on the second side. That is, the semiconductor layer 3 is sandwiched between the source electrode 4 and the drain electrode 5. The source electrode 4 and the gate electrode 7 are not directly electrically connected to each other.

The semiconductor chip 1 is mounted on the frame 2 via the solder 30. The frame 2 and the drain electrode 5 are electrically connected (e.g. via the solder 30). The frame 2 includes a plurality of pins protruding in a first direction (upward direction in FIG. 1). According to the depicted example embodiments, the frame 2 includes four pins, but in other embodiments a different number of pins may be implemented. The pins protruding from the frame 2 can function as a drain terminal D.

The source connector 10 includes a chip connection 11, a source terminal connection 12 (a first connection), and a kelvin-source terminal connection 13 (a second connection). The chip connection 11 is provided on the source electrode 4. At least one portion of the chip connection 11 is electrically connected to the source electrode 4 via the solder 30.

As shown in FIG. 1, the source terminal connection 12 and the kelvin-source terminal connection 13 are each connected to the chip connection 11. The source terminal connection 12 and the kelvin-source terminal connection 13 protrude in a second direction opposite to the first direction (downward direction in FIG. 1). The source terminal connection 12 and the kelvin-source terminal connection 13 have substantially the same potential (as they are, for example, electrically connected via the chip connection 11), but are not in physical contact with each other (e.g. are horizontally spaced apart, as shown in FIG. 1). The source terminal connection 12 and the kelvin-source terminal connection 13 are physically spaced apart from each other. As shown in FIG. 2, the source terminal connection 12 and the kelvin-source terminal connection 13 of the source connector 10 are provided physically apart from the semiconductor chip 1 (separated in a vertical direction in FIG. 2). Thus, the source terminal connection 12 and the kelvin-source terminal connection 13 are not in physical contact with the semiconductor chip 1. Although the depicted embodiments show a single source terminal connection 12 and a single kelvin-source terminal connection 13, in other embodiments more than one source terminal connections 12 and/or more than one kelvin-source terminal connections 13 can be implemented.

The source terminal S1 is connected to the source terminal connection 12 via the solder 30. The source terminal S1 includes a plurality of pins protruding in the second direction. In the depicted example embodiments, the source terminal S1 includes two pins, but a different number of pins may be implemented.

The kelvin-source terminal S2 is connected to the kelvin-source terminal connection 13 via the solder 30. The kelvin-source terminal S2 includes a pin protruding in the second direction. In the depicted example embodiments, the source terminal S2 includes a single pin, but a different number of pins may be implemented. The source terminal S1 and the kelvin-source terminal S2 extend in a same direction (e.g. are parallel to each other), but are not in physical contact with each other.

At least portion of the gate connector 20 is electrically connected to the gate electrode 7 via the solder 30. The gate terminal G is electrically connected to the gate connector 20 via the solder 30. The gate terminal G includes a pin protruding in the second direction. In the depicted example embodiments, the gate terminal G includes a single pin, but a different number of pins may be implemented.

The passivation layer 6 is provided on the semiconductor chip 1. The passivation layer 6 can help to prevent the invasion of ions or moisture from outside the semiconductor device 100. Also, the passivation layer 6 can help to prevent the solder adhering to other components during package assembly.

For example, the frame 2, the source connector 10, the gate connector 20, the source terminal S1, the kelvin-source terminal S2, and the gate electrode G include metal material such as copper. For example, the source electrode 4, the drain electrode 5, and the gate electrode 7 include metal material such as aluminum. For example, the passivation layer 6 includes polyimide or a combination material including oxide film and nitride film.

The semiconductor device 100 can be overmolded and/or undermolded by resin (not shown in the Figures). At least a portion of the pins of each of the frame 2, the source terminal S1, the kelvin-source terminal S2, and the gate terminal G are exposed from resin. The exposed pins can be connected to an external power supply or other external devices.

FIG. 3 is a circuit diagram showing embodiments of the semiconductor device 100 according to the first aspect connected to a boost chopper. The depicted embodiments of a semiconductor module 600 include the semiconductor device 100. The semiconductor module 600 includes the semiconductor device 100, a resistance R, a capacitor C, a diode D, a coil L, and a gate driver 40. As shown in FIG. 3, a drain current I_{D} flows in the arrow direction through the coil L and the semiconductor device 100. Signal Ho or signal Lo is output from the gate driver 40. The semiconductor device 100's on/off function is controlled with the signal Ho or the signal Lo input to the gate electrode 7 of the semiconductor device 100. A gate current I_{G} from the gate driver 40 returns to the gate driver 40 through the semiconductor device 100 and the kelvin-source terminal S2.

### (Effect)

Some effects of the semiconductor device 100 according to the first embodiment will now be described using a comparative example. FIG. 4 is a top view showing some embodiments of a semiconductor device 200 according to a first comparative example.

The semiconductor device 200 according to the first comparative example differs from the semiconductor device 100 according to the first aspect in that the semiconductor device 200 does not include the kelvin-source terminal connection 13. The source connector 10 of the semiconductor device 200 includes the chip connection 11 and the source terminal connection 12, and does not include the kelvin-source terminal connection 13. The source terminal connection 12 of the semiconductor device 200 is electrically connected to the source terminal S1. The semiconductor device 200 includes same and/or similar components as the semiconductor device 100, other than the above described deviation.

FIG. 5 is a circuit diagram showing some embodiments of the semiconductor device 200 according to the first comparative example connected to a boost chopper. A depicted semiconductor module 700 includes the semiconductor device 200, a resistance R, a capacitor C, a diode D, a coil L, and a gate driver 40. The semiconductor device 200 can be switched to the on-state by applying a voltage not less than a threshold to the gate electrode 7. At this time, a drain current I_{D} flows from the drain terminal D to the source terminal S1. A gate current I_{G} flows from the gate terminal G to the source terminal S1. The drain current I_{D} is much larger than the gate current I_{G}.

The source connector 10 includes a parasitic source inductance. As shown in the following equation (1), V_{GS} is higher than V_{G} when the rate of change of I_{D} plus I_{G} is positive, because the drain current I_{D} flows through the parasitic source inductance. In equation (1), V_{G} is the gate driver voltage of the gate driver output, V_{GS} is the driver voltage between the gate and the source in the semiconductor device 100, I_{G} is the gate current, I_{D} is the drain current, and L_{S} is the parasitic source inductance.

V_{GS}=V_{G}+L_{S}·d(I_{D}+I_{G})/dt (1)

The driver voltage V_{GS} is added to the intended V_{G} due to the electromotive force caused by I_{D} flowing through L_{S}. That is, the semiconductor chip 1 causes an unintentional voltage difference from an intended V_{G}. This mechanism can lead to malfunction of the semiconductor device 200. This malfunction of the semiconductor device 200 may cause undesirable noise.

On the other hand, in the semiconductor device 100 according to the first aspect, the kelvin-source terminal S2 is electrically isolated from the source terminal S1. Thus, V_{GS} is less affected by I_{D}. The kelvin-source terminal connection 13 of the semiconductor device 100 may include some parasitic source inductance. But the affect is relatively small, because the gate current I_{G} is much smaller than the drain current ID. V_{GS} thus has a value as shown in the following equation (2). In the equation (2), L_{S}′ is the parasitic inductance of the kelvin-source terminal connection 13.

V_{GS}=V_{G}+L_{S}′·dI_{G}/dt (2)

As described above, because the semiconductor device 100 according to the first embodiment includes the kelvin-source terminal S2, the electromotive force caused by the parasitic inductance affects the semiconductor device to a lesser degree. Thus noise caused by malfunction of the semiconductor device may be reduced.

Furthermore, if a semiconductor device does not include the kelvin-source terminal S2, the gate driver 40 might not detect the driver voltage V_{GS} correctly due to the drain current I_{D} flowing through the parasitic inductance L_{S}. But, with the kelvin-source terminal S2, the gate driver 40 can correctly detect the driver voltage V_{GS}.

A further desired property of a semiconductor device may be a low or reduced on-resistance.

A reduction of package-resistance effects which can help to reduce the on-resistance of a semiconductor device are described herein. One of the methods to reduce the package-resistance is to reduce the interconnection-resistance. According to some embodiments described herein, the interconnection-resistance may be reduced because the source connector 10 covers the source electrode of the semiconductor chip 1. This reduction of the interconnection-resistance may lead to a reduction of the package-resistance of the semiconductor device.

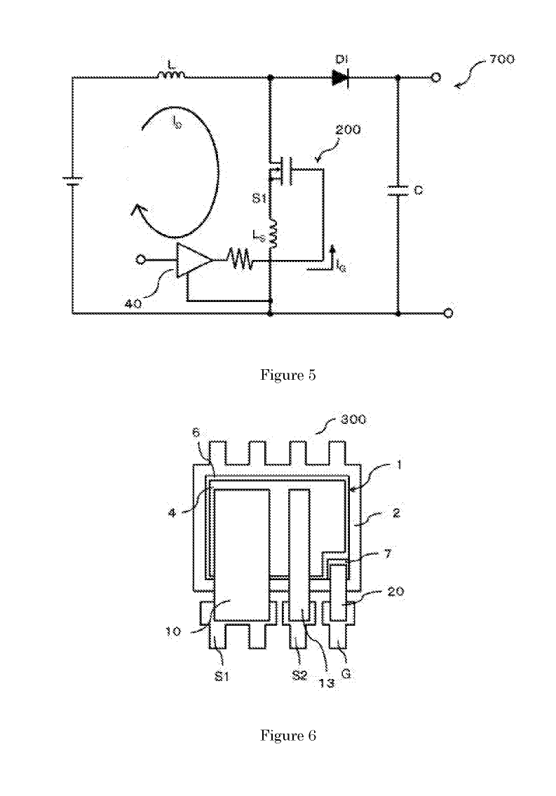

In a semiconductor device including a kelvin source connection, a component may be included which allows for interconnection between a chip 1 and a kelvin source terminal. However, such a component may prevent the reduction of the package-resistance, because this component is not necessarily covered by a metal connector. This potential detriment will now be described with respect to FIG. G. FIG. 6 is a top view showing some embodiments of a semiconductor device 300 according to a second comparative example.

As shown in FIG. 6, the source connector 10 is divided into two parts and both parts are connected to the source electrode 4 on the semiconductor device 1. One part of the source connector 10 may function in a manner similar to the source connector 10 of the semiconductor device 100. The other part of the source connector 10 may function in manner similar to the kelvin-source terminal connection 13 of the semiconductor device 100. The area of semiconductor chip 1 may be increased to help electrically connect the chip to the kelvin-source terminal connection 13. This increase of area may prevent effective use of the semiconductor chip 1. Furthermore, the interconnect-resistance may increase if a only smaller portion of the source electrode 4 is covered by the source connector 10 as compared to configuration of the semiconductor device 100. Also, manufacturing cost may increase, and manufacturing productivity may decrease because of the increased number of components of the source connector 10.

By way of comparison, as show in FIG. 1, in the semiconductor device 100 according to the first aspect, a larger portion of the source electrode 4 in the semiconductor chip 1 is covered by the source connector 10. The interconnect-resistance may thus be lower than the second comparative example shown in FIG. G. Additionally, it may not be necessary to increase the area of semiconductor chip 1 used to electrically interconnect to the kelvin-source terminal connection 13. Also, manufacturing cost may be lower because the source connector 10 can be made from fewer components.

The effect of the parasitic inductance in the semiconductor device 100 is substantially equal to that of the semiconductor device 300. This is because two components of the source connector 10 are electrically connected via the source electrode 4 to the semiconductor chip 1.

It may be desirable for a gap between the source connector 10 and the kelvin-source terminal connection 13 to be narrow, to avoid the necessity of enlarging an interconnection element (such as the solder 30) of the semiconductor device. But too narrow gap may cause coupling between the source terminal connector 12 and the kelvin-source terminal connection 13. So, to help prevent this coupling, the source terminal connector 12 and the kelvin-source terminal connection 13 can be connected via the chip connection 11.

According to some embodiments of the semiconductor device 100, the source terminal connector 12 and the kelvin-source terminal connection 13 protrude in a same direction. This can help to make an arrangement of pins of the source terminal connector 12 and the kelvin-source terminal connection 13 compatible with the existing package. Alternatively, the source connector 10 and the kelvin-source terminal connection 13 may protrude in different directions.

While the semiconductor device embodiments have been described as using MOSFET, other implementations are also possible. For example, the semiconductor device may be implemented with an insulated-gate bipolar transistor (IGBT) or other transistor.

The kelvin-source terminal connection 13 can be manufactured by dividing the source connector 10 (e.g., by dividing the source connector 10 into a source terminal connector 12 and a kelvin-source terminal connection 13). With such a kelvin-source terminal connection 13, noise may be reduced and interconnection-resistance may be lowered or kept small.

### (A First Modification of the First Aspect)

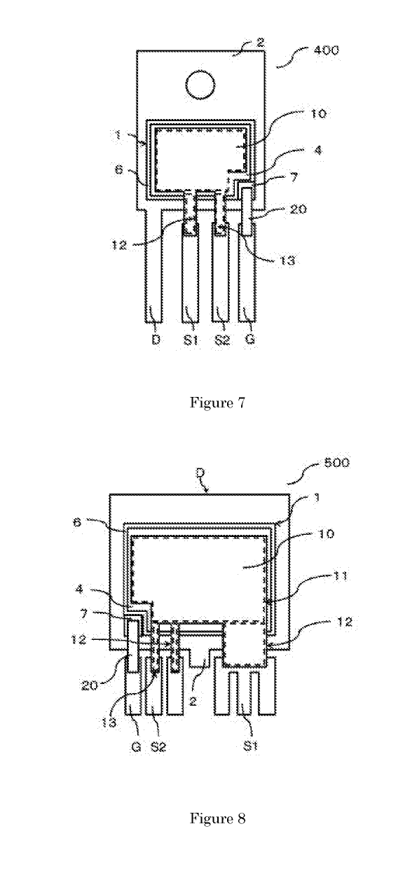

Some embodiments of the semiconductor device according to a first modification of the first aspect will now be described with reference to FIG. 7. FIG. 7 is a top view showing some embodiments of a semiconductor device 400 according to the first modification of the first aspect. The semiconductor device 400 differs from the semiconductor device 100 in that the drain terminal D protrudes in a same direction as the source terminal S1, the kelvin-source terminal S2, and the gate terminal G. The drain terminal D, the source terminal S1, the kelvin-source terminal S2, and the gate terminal G can be provided in the arrangement shown in FIG. 7, but other embodiments may employ different arrangements.

It may be desirable for a gap between the source terminal connector 12 and the kelvin-source terminal connection 13 to be narrow, because otherwise a required area of an interconnection component of the chip 1 (e.g. the solder 30) may be large. But too narrow gap may cause coupling between the source terminal connector 12 and the kelvin-source terminal connection 13. So, to help prevent such coupling in the semiconductor device 400 while lowering or keeping the interconnect-resistance small, the source terminal connector 12 and the kelvin-source terminal connection 13 can be connected via the chip connection 11.

In the first modification, similar to the semiconductor device 100, noise may be reduced by using the kelvin-source terminal connection 13. Also, interconnect-resistance and manufacturing productivity may be lowered by connecting the source terminal connector 12 and the kelvin-source terminal connection 13 to the semiconductor chip 1.

### (Second Modification of the First Aspect)

Some embodiments of the semiconductor device according to a second modification of the first aspect will now be described with reference to FIG. 8. FIG. 8 is a top view showing a semiconductor device 500 according to the second modification of the first aspect. The semiconductor device 500 includes a source terminal 12 of the source connector 10 divided into two parts. The semiconductor device 500 includes eight lead terminals (including, for example, the drain terminal D). The semiconductor device 500 according to the second modification includes a chip connection 11 of the source connector 10 that more fully covers the semiconductor chip 1 than does that of the semiconductor device 100 (e.g. by having an edge adjacent to and/or parallel to an edge of the source electrode 4). In the semiconductor device 500 according to the second modification, the source terminal connection 12 and the kelvin-source terminal connection 13 both protrude from the chip connection 11. Although the semiconductor device 500 includes two source terminals, in other embodiments a different number of source terminals may be implemented.

It may be desirable for a gap between the source terminal connector 12 and the kelvin-source terminal connection 13 to be narrow, because otherwise a required area of an interconnection component of the chip 1 (e.g. the solder 30) may be large. But too narrow a gap may cause coupling between the source terminal connector 12 and the kelvin-source terminal connection 13. So, to prevent such coupling in the semiconductor device 500, while lowering or keeping the interconnect-resistance small, the source terminal connector 12 and the kelvin-source terminal connection 13 may be connected via the chip connection 11.

According to the second aspect, the source terminal S1 and the kelvin-source terminal S2 protrude in a same direction, which can help to make an arrangement of pins of the source terminal connector 12 and the kelvin-source terminal connection 13 compatible with the existing package. Alternatively, the source terminal S1 and the kelvin-source terminal S2 may protrude in different directions.

In the second modification, as in the semiconductor device 100, noise may be reduced by using the kelvin-source terminal connection 13. Also, interconnect-resistance and manufacturing productivity may be lowered with the two connectors connected to the semiconductor chip.

In the description of some embodiments, a component provided “on” or “over” another component can encompass cases where the former component is directly on (e.g., in physical contact with) the latter component, as well as cases where one or more intervening components are located between the former component and the latter component.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

While certain embodiments have been described, these embodiments have been presented by way of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The specific structures of components shown in the embodiments may be chosen appropriately by persons skilled in art. The accompanying claims and their equivalents are intended to cover such forms or modifications as would fall within the scope and spirit of the present disclosure. The respective embodiments may be implemented in combination with each other. Moreover, some or all of the above described embodiments can be combined when implemented.

What is claimed is:

1. A semiconductor device, comprising:
a semiconductor chip including a first terminal, a second terminal and a third terminal;
a frame electrically coupled to the second terminal, the frame mounting the semiconductor chip;
a first conductor including:
a chip connection electrically coupled to the first terminal;
a first connection connecting to the chip connection and protruding from the chip connection;
a second connection connecting to the chip connection, protruding from the chip connection, and being provided physically spaced from the first connection; and
a second conductor electrically coupled to the third terminal.

2. The semiconductor device according to claim 1, further comprising:
a plurality of first connections including the first connection, each first connection connecting to the chip connection and protruding from the chip connection.

3. The semiconductor device according to claim 1,
wherein the chip connection, the first connection, and the second connection include a same material.

4. The semiconductor device according to claim 1,
wherein at least one part of the first connection is provided just above the semiconductor chip.

5. The semiconductor device according to claim 1, further comprising a gate driver configured to apply a gate voltage between the second connection and the second conductor.

6. The semiconductor device according to claim 1, further comprising:
a plurality of second connections including the second connection, each second connection connecting to the chip connection, protruding from the chip connection, and being provided physically spaced from the first connection.

7. A semiconductor module, comprising:
a semiconductor chip including a first terminal, a second terminal and a third terminal;
a frame electrically coupled to the second terminal, the frame mounting the semiconductor chip;
a first conductor including;
a chip connection electrically coupled to the first terminal;
a first connection connecting to the chip connection and protruding from the chip connection;
a second connection connecting to the chip connection, protruding from the chip connection, and being provided physically spaced from the first connection;
a second conductor electrically coupled to the third terminal; and
a gate driver connected to the second connection and the second conductor.

8. The semiconductor module according to claim 7, further comprising:
a plurality of first connections including the first connection, each first connection connecting to the chip connection and protruding from the chip connection.

9. The semiconductor module according to claim 7, further comprising:
a plurality of second connections including the second connection, each second connection connecting to the chip connection, protruding from the chip connection, and being provided physically spaced from the first connection.
